(19) United States
(12) Patent Application Publication
(10) Pub. No.: US 2013/0087756 A1
(43) Pub. Date: Apr. 11, 2013

(54) HEAT SHIELD LINER IN A PHASE CHANGE MEMORY CELL

(71) Applicants: Eric A. Joseph, White Plains, NY (US); Chung H. Lam, Peekskill, NY (US); Son V. Nguyen, Schenectady, NY (US); Alejandro G. Schrott, New York, NY (US)

(72) Inventors: Eric A. Joseph, White Plains, NY (US); Chung H. Lam, Peekskill, NY (US); Son V. Nguyen, Schenectady, NY (US); Alejandro G. Schrott, New York, NY (US)

(73) Assignee: International Business Machines Corporation, Armonk, NY (US)

(21) Appl. No.: 13/268,151

(22) Filed: Oct. 7, 2011

(51) Int. Cl. H01L 47/00; H01L 21/02

(52) U.S. Cl. 257/4; 438/382; 257/E47.001; 257/E21.004

(57) ABSTRACT

A memory cell structure and method to form such structure. An example memory cell includes a bottom electrode formed within a substrate. The memory cell also includes a phase change memory element in contact with the bottom electrode. The memory cell includes a liner laterally surrounding the phase change memory element. The liner includes dielectric material that is thermally conductive and electrically insulating. The memory cell includes an insulating dielectric layer laterally surrounding the liner. The insulating dielectric layer includes material having a lower thermal conductivity than that of the liner.

### BACKGROUND

This invention relates to phase change memory cells, and more particularly, a phase change memory cell with a heat shield liner.

There are two major groups in computer memory: non-volatile memory and volatile memory. Constant input of energy in order to retain information is not necessary in non-volatile memory but is required in the volatile memory. Examples of non-volatile memory devices are Read Only Memory (ROM), Flash Electrical Erasable Read Only Memory, Ferroelectric Random Access Memory, Magnetic Random Access Memory (MRAM), and Phase Change Memory (PCM); non-volatile memory devices being memory in which the state of the memory elements can be retained for days to decades without power consumption. Examples of volatile memory devices include Dynamic Random Access Memory (DRAM) and Static Random Access Memory (SRAM); where DRAM requires the memory element to be constantly refreshed while SRAM requires a constant supply of energy to maintain the state of the memory element. The present invention is directed to phase change memory. In phase change memory, information is stored in materials that can be manipulated into different phases. Each of these phases exhibit different electrical properties which can be used for storing information. The amorphous and crystalline phases are typically two phases used for bit storage (1's and 0's) since they have detectable differences in electrical resistance. Specifically, the amorphous phase has a higher resistance than the crystalline phase.

Chalcogenides are a group of materials commonly utilized as phase change material. This group of materials contain a chalcogen (Periodic Table Group 16/VIA) and another element. Selenium (Se) and tellurium (Te) are the two most common semiconductors in the group used to produce a chalcogenide when creating a phase change memory cell. An example of this would be Ge2Sb2Te5 (GST), SbTe, and In2Se3.

In phase change memory, the heat necessary to drive a change between states in the phase change material propagates to adjacent materials. Heat propagating into adjacent memory cells may cause thermal cross-talk and errors in bit storage. Thus it is desirable to channel the heat away from the adjacent memory cells.

### SUMMARY

One aspect of the invention is a memory cell structure. The memory cell includes a bottom electrode formed within a substrate, wherein the bottom electrode has a top surface. The memory cell also includes a phase change memory element in contact with the top surface of the bottom electrode. The memory cell includes a liner laterally surrounding the phase change memory element. The liner includes dielectric material that is thermally conductive and electrically insulating. The memory cell includes an insulating dielectric layer laterally surrounding the liner. The insulating dielectric layer includes material having a lower thermal conductivity than that of the liner.

Another aspect of the invention is a method for fabricating a memory cell. The method includes forming a bottom electrode within a substrate. The method also includes forming an insulating dielectric layer over the bottom electrode. The method includes forming a via within the insulating dielectric layer over the center of the bottom electrode. The via includes at least one sidewall. The method also includes forming a liner along at least one sidewall of the via. The liner includes dielectric material that is thermally conductive and electrically insulating. The liner material has a thermal conductivity higher than that of the dielectric layer. The method also includes etching a portion of the liner, exposing a portion of the bottom electrode. The method includes forming a phase change memory layer within the via.

### BRIEF DESCRIPTION OF THE DRAWINGS

FIG. 1 shows a bottom electrode formed within a substrate in accordance with one embodiment of the present invention.

FIG. 2 shows an insulating dielectric layer formed on the bottom electrode and substrate in accordance with one embodiment of the present invention.

FIG. 3 shows a memory cell after selectively etching the insulating dielectric layer in accordance with one embodiment of the present invention.

FIG. 4 shows a memory cell after depositing a liner layer, creating a keyhole formation in accordance with one embodiment of the present invention.

FIG. 5 shows a memory cell after etching the liner layer to reopen the via for forming the phase change memory element in accordance with one embodiment of the present invention.

FIG. 6 shows an example memory cell in accordance to one embodiment of the present invention.

FIG. 7 shows an embodiment wherein a top electrode is formed over the phase change memory element after planarization.

FIG. 8 shows an alternate embodiment of the present invention, in which a spacer exists between the phase change memory element and the liner.

FIG. 9 shows a flowchart illustrating an example method for forming a memory cell contemplated by the present invention.

FIGS. 10a and 10b display a continuous flowchart illustrating an example embodiment of a method for forming a memory cell in accordance with the present invention.

### DETAILED DESCRIPTION

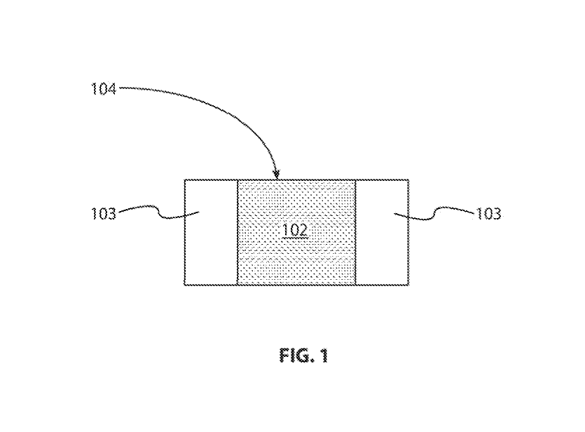

The present invention is described with reference to embodiments of the invention, but shall not be limited to the referenced embodiments. Throughout the description of the present invention, references are made to FIGS. 1 through 10b.

Additionally, relative terms, such as “top”, “bottom”, “up” and “down” are employed with respects to other elements in the described embodiments and figures. Such terms are meant only to describe the referenced embodiments. Therefore, the present invention encompasses alternative orientations of the suggested embodiments.

Embodiments of the present invention provide possible memory cell structures and methods of fabricating such structures. An aspect of the present invention provides a method of reducing the lateral heat propagation during phase change memory element heating. A reduction in lateral heat propagation is advantageous in preventing crosstalk between memory cells.

FIGS. 1 through 5 are example intermediary steps during fabrication of a memory cell 100 in accordance with the present invention.

FIG. 1 shows a bottom electrode 102 formed within a substrate 103. The bottom electrode includes a top surface 104. One skilled in the art will recognize that the bottom electrode 102 can be composed of a variety of conductive materials, such as ruthenium (Ru) or tantalum-ruthenium (TaRu), titanium nitride (TiN), Tantalum silicon nitride (TaSiN). The substrate 103 material can be a variety of materials recognized by one skilled in the art, for example, silicon (Si), germanium (Ge) or silicon dioxide (SiO), and Silicon oxinitride (SiON).

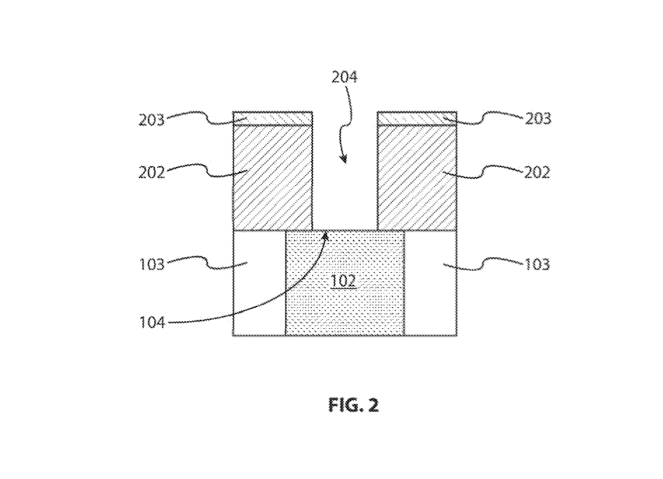

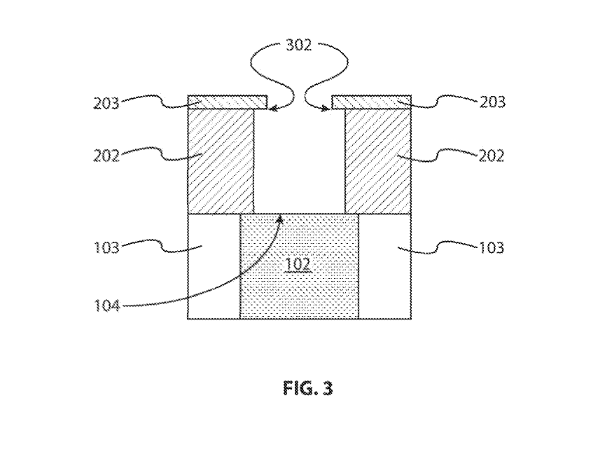

FIG. 2 is an illustrative example showing an insulating dielectric layer 202 formed on the bottom electrode 102 and substrate 103. The insulating dielectric layer 202 can be composed of a thermally insulating oxide. In this embodiment, a second dielectric layer 203 formed on the insulating dielectric layer 202. Also illustrated, is a via 204 is formed over the top surface of the bottom electrode 104, through the dielectric layers 202 and 203. Those skilled in the art will recognize that the via 204 can be formed with a lithographic mask followed by a reactive-ion etch (RIE).

FIG. 3 shows the memory cell 100 after selectively etching the insulating dielectric layer 202. The etch produces an overhang 302, wherein the second dielectric 203 extends further into the via 204 than the insulating dielectric 202. In order to selectively etch the insulating dielectric 202, the second dielectric layer 203 can be comprised of a variety of different dielectric materials, such as silicon nitride (SiN). Such overhang provides a keyhole formation during the deposition of a liner layer.

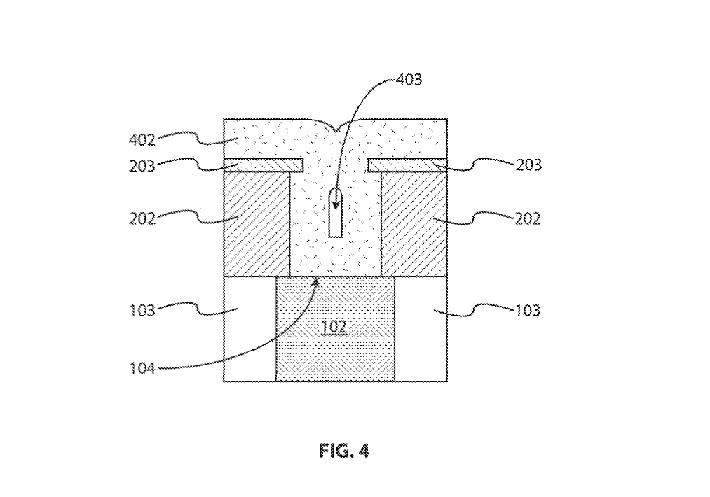

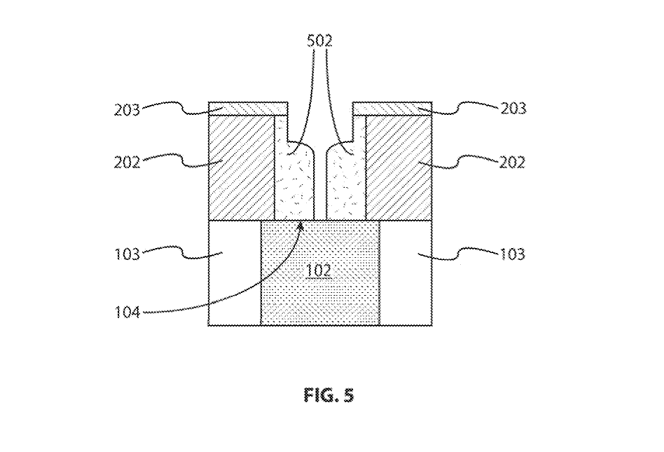

FIG. 4 schematically depicts a liner layer 402 deposited, creating a keyhole formation 403. The liner layer 402 can be comprised of a variety of dielectric materials that are thermally conductive and electrically insulating, wherein the thermal conductivity is higher than that of the insulating dielectric layer 202. Such materials include but are not limited to boron nitride (BN), aluminum nitride (AlN), silicon nitride (SiN), and/or aluminum oxide (AlO). Furthermore, a variety of processes can be utilized to conformally deposit the liner layer 402, for example, atomic-layer deposition (ALD) or plasma-enhanced atomic-layer deposition (PALD).

FIG. 5 shows an intermediary step during fabrication after etching the liner layer 402 to reopen the via for forming the phase change memory element 602. Etching the liner layer 402 produces a liner 502 along the sidewall of the insulating dielectric 202. One skilled in the art would recognize that an anistropic etch can be utilized to produce such a structure.

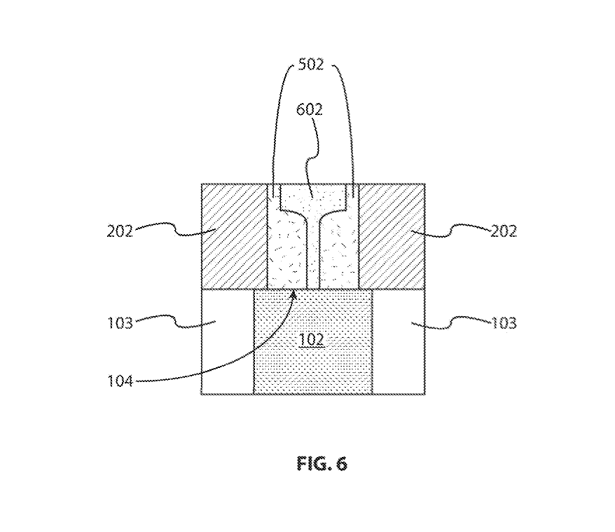

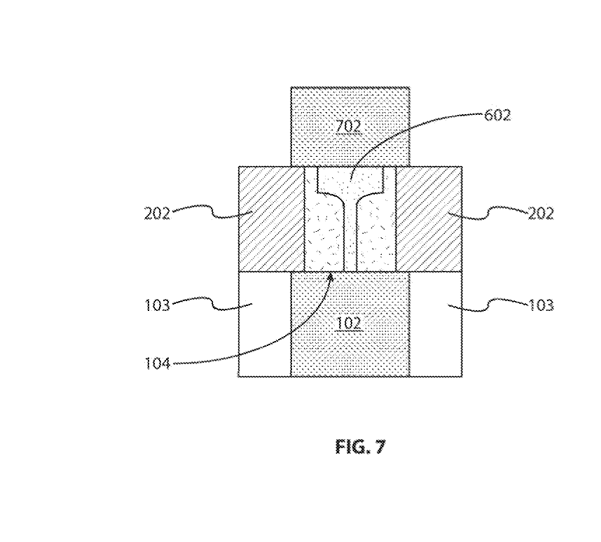

FIG. 6 shows the example memory cell 100 in accordance to one embodiment of the present invention. The memory cell 100 includes the bottom electrode 102 formed within the substrate 103, wherein the bottom electrode 102 has a top surface 104. The memory cell also includes the phase change memory element 602 in contact with the top surface 104 of the bottom electrode 102. One skilled in the art will recognize that a variety of materials can be utilized for the phase change memory element, for example, Germanium-Antimony-Tellurium (GST). Typically, the top surface of the memory cell 603 is polished by chemical-mechanical planarization (CMP).

The memory cell of FIG. 6 also includes the liner 502 laterally surrounding the phase change memory element 602. In some embodiments, the material of the liner 502 may provide wetting properties for forming the phase change memory element 602. Laterally surrounding the liner 502, is the insulating dielectric layer 202. The insulating dielectric layer 202 can be composed of material having a lower thermal conductivity than that of the liner 502.

FIG. 7 shows an embodiment wherein a top electrode 702 is formed over the phase change memory element 602 after planarization.

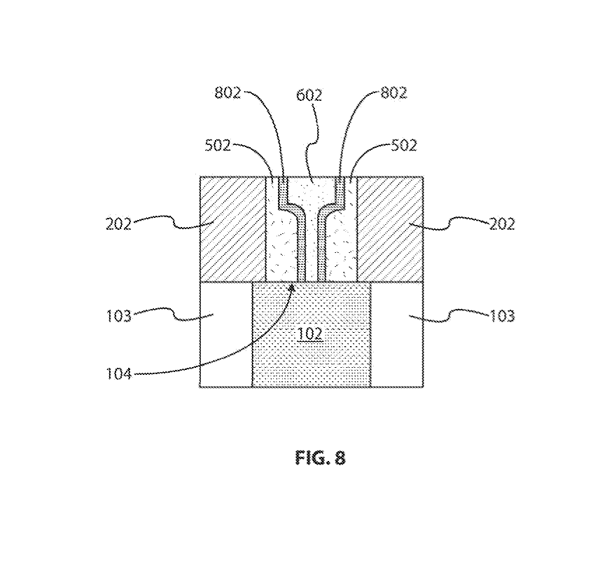

FIG. 8 shows an alternate embodiment of the present invention, in which a spacer 802 exists between the phase change memory element 602 and the liner 502. The spacer 802 further reduces the via diameter and provides wetting properties with the phase change memory element 602. Like the liner 502, the spacer 802 can be comprised of a variety of thermally conductive and electrically insulating dielectrics and can be conformally deposited atomic-layer deposition (ALD) or plasma-enhanced atomic-layer deposition (PALD). In some embodiments, the spacer 802 can be a few monolayers thick, wherein an etch is not necessary to allow contact between the phase change memory element 602 and the top surface of the bottom electrode 104.

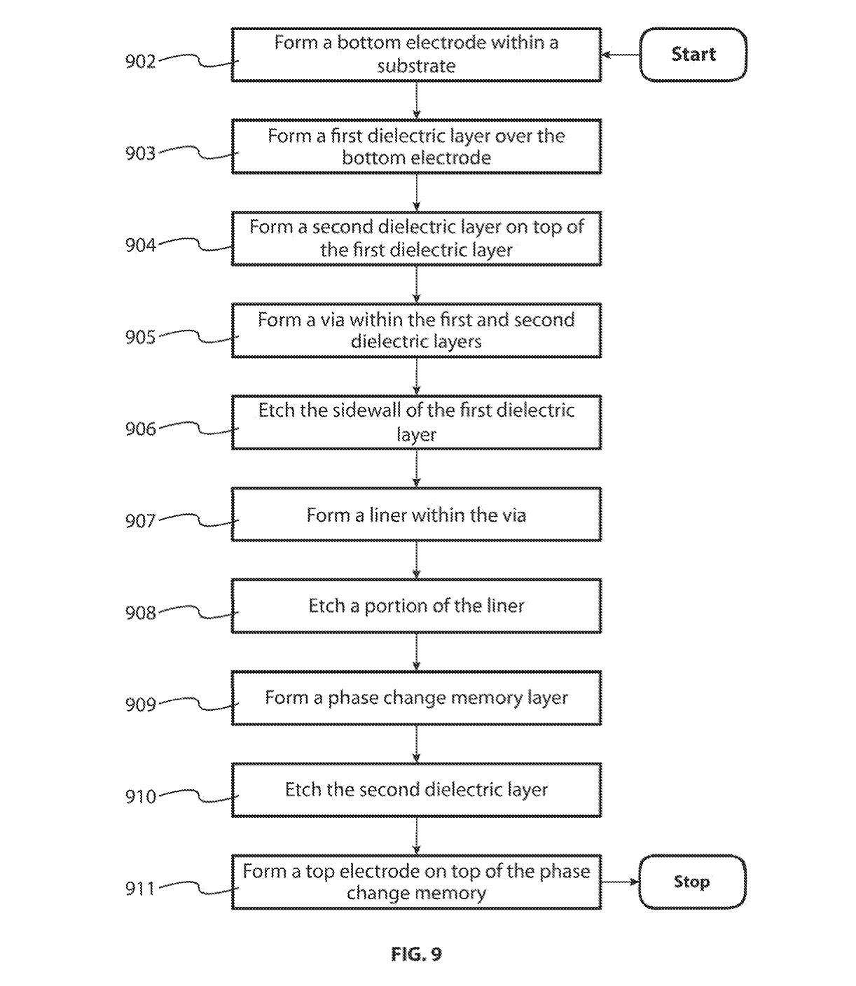

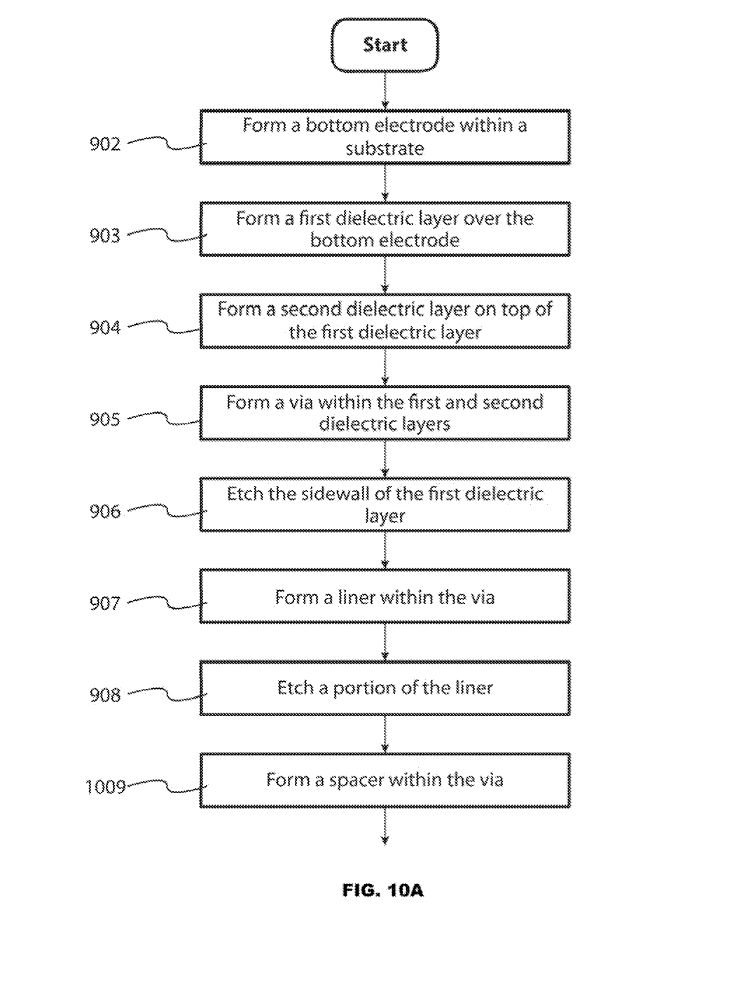

Now turning to FIG. 9, a flowchart illustrating an example method for forming a memory cell contemplated by the present invention is presented. The method begins with forming step 902. At forming step 902, a bottom electrode 102 is formed within a substrate 103, as illustrated in FIG. 1. After forming step 902 is completed, the method continues to forming step 903.

At forming step 903, an insulating dielectric layer 202 is formed over the bottom electrode 102. After forming step 903 is completed, the method continues to forming step 904.

At forming step 904, a second dielectric layer 203 is formed over the insulating dielectric layer 202. After forming step 904 is completed, the method continues to forming step 905.

At forming step 905, a via 204 is formed in the insulating dielectric layer 202 and the second dielectric layer 203, over the center of the bottom electrode 102, as illustrated in FIG. 2. The via 204 includes at least one sidewall. After forming step 905 is completed, the method continues to etching step 906.

At etching step 906, a portion of the insulating dielectric layer 202 sidewall is etched to produce an overhang 302, as illustrated in FIG. 3. After etching step 906 is completed, the method continues to forming step 907.

At forming step 907, a liner layer 402 is formed in the via 204 to produce a keyhole formation 403, as illustrated in FIG. 4. The liner layer 402 is comprised of a material that is a thermally conductive and electrically insulating dielectric. Additionally, the liner layer material has a higher thermal conductivity than the insulating dielectric layer 202. Examples of such materials are boron nitride (BN), aluminum nitride (ALN), silicon nitride (SiN), and/or aluminum oxide (AlO). In some embodiments, the liner layer material may provide wetting properties for forming a phase change material element 602. Additionally, a variety of processes may be utilized to form the liner layer 402, such as Atomic Layer Deposition (ALD) or Plasma-Enhanced Atomic Layer Deposition (PALD). After forming step 907 is completed, the method continues to etching step 908.

At etching step 908, a portion of the liner layer 402 is etched to expose a portion of the bottom electrode 102, resulting in a liner 502, as illustrated in FIG. 5. After etching step 908 is completed, the method continues to forming step 909.

At forming step 909, the phase change memory element 602 is formed within the via 204. After forming step 909 is completed, the method continues to etching step 910.

At etching step 910, the second dielectric layer 203 is removed by etching. One example embodiment is illustrated in FIG. 6. After etching step 910, the method continues to forming step 911.

At forming step 911, a top electrode 702 is formed over the phase change memory element 602. After forming step 911, the method ends.

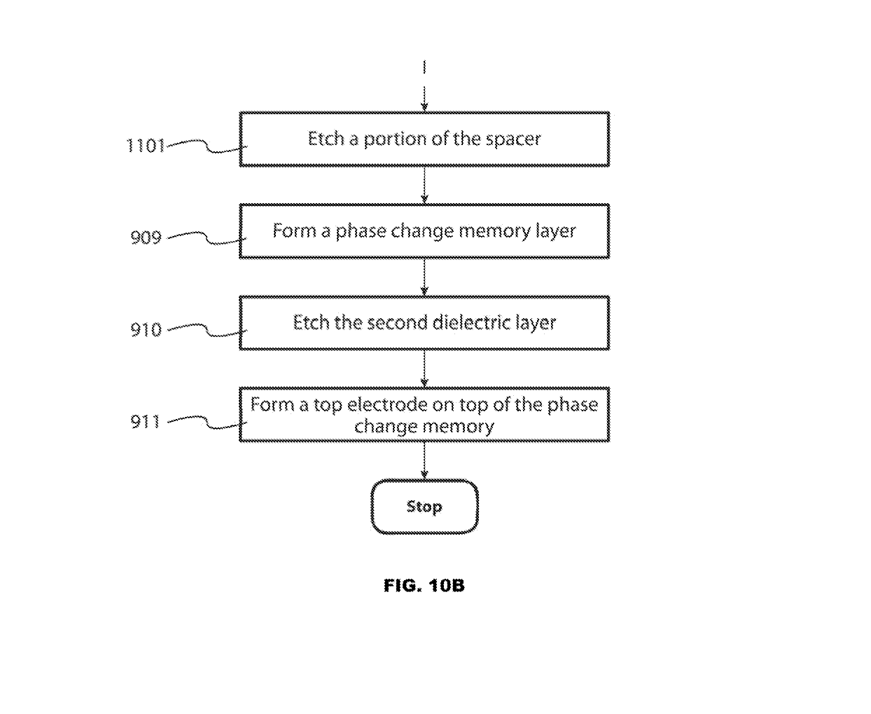

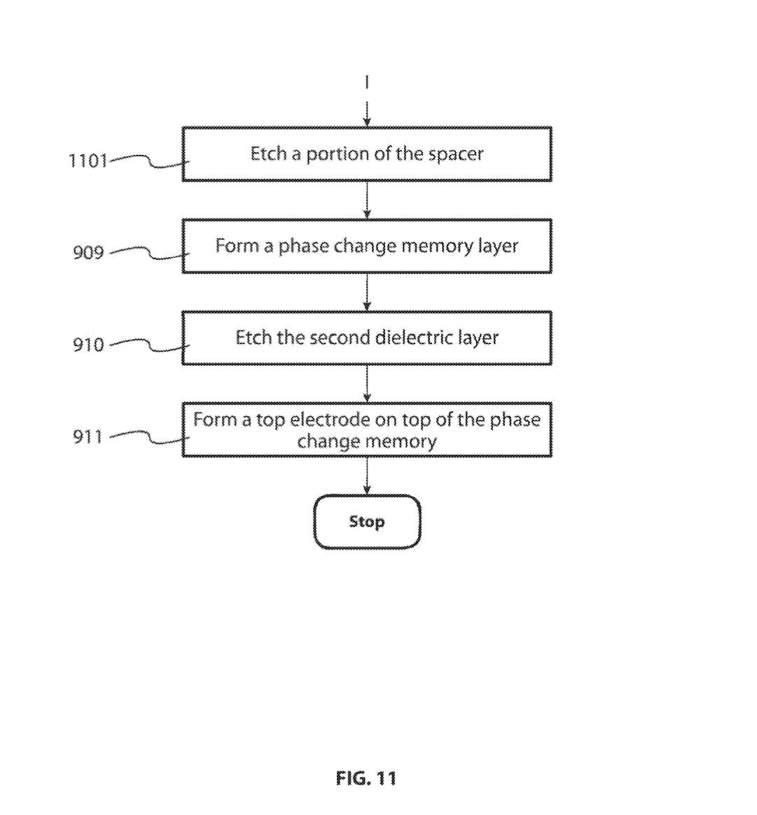

FIGS. 10a and 10b, display a continuous flowchart illustrating another example embodiment of the method for forming a memory cell in accordance with the present invention. In this embodiment, the method may also include steps 902-911 described above. Additionally, after etching step 908, the method continues to forming step 1009.

At forming step 1009, a spacer 802 is formed in the via 204 along the liner 502. The spacer 802 being composed of a material having a higher thermal conductivity than the liner 502. In some embodiments, the spacer material may provide wetting properties for forming a phase change material element 602. Additionally, a variety of processes may be utilized to form the spacer 802, such as Atomic Layer Deposition (ALD) or Plasma-Enhanced Atomic Layer Deposition (PALD). After forming step 1009 is completed, the method continues to etching step 1101.

At etching stop 1101, a portion of the spacer 802 is etched to expose a portion of the bottom electrode 102. After etching step 1101 is completed, the method continues to forming step 909 and proceeds as described above with reference to FIG. 9. An example resulting memory cell in accordance to this embodiment is illustrated in FIG. 8.

Having described preferred embodiments for a memory cell structure and the method for forming such a memory cell structure (which are intended to be illustrative and not limiting), it is noted that modifications and variations can be made by persons skilled in the art in light of the above teachings. It is therefore to be understood that changes may be made in the particular embodiments disclosed which are within the scope and spirit of the invention as outlined by the appended claims. Having thus described aspects of the invention, with the details and particularity required by the patent laws, what is claimed and desired protected by Letters Patent is set forth in the appended claims.

What is claimed is:

1. A memory cell, comprising:
a bottom electrode formed within a substrate, wherein the bottom electrode has a top surface;
a phase change memory element in contact with the top surface of the bottom electrode;
a liner laterally surrounding the phase change memory element, the liner being composed of material that is thermally conductive and electrically insulating dielectric; and
an insulating dielectric layer laterally surrounding the liner, the insulating dielectric layer is composed of material having a lower thermal conductivity than that of the liner.

2. The memory cell of claim 1, wherein the liner material provides wetting properties for forming the phase change memory element.

3. The memory cell of claim 1, wherein the liner is composed of boron nitride (BN), aluminum nitride (AlN), silicon nitride (SiN), and/or aluminum oxide (AlO).

4. The memory cell of claim 1, further comprising a top electrode over the phase change memory element.

5. The memory cell of claim 1, further comprising a spacer between the phase change memory element and the liner, the spacer being composed of material having a higher thermal conductivity than the liner.

6. The memory cell of claim 5, wherein the spacer has a thickness less than the liner.

7. The memory cell of claim 6, wherein the spacer material provides wetting properties for forming the phase change memory element.

8. A method for fabricating a memory cell, comprising:
forming a bottom electrode within a substrate;
forming an insulating dielectric layer over the bottom electrode;
forming a via within the insulating dielectric layer over the center of the bottom electrode, the via including at least one sidewall;
forming a liner along at least one sidewall of the via, the liner being composed of material that is thermally conductive and electrically insulating dielectric, wherein the liner material has a thermal conductivity higher than that of the dielectric layer;
etching a portion of the liner, exposing a portion of the bottom electrode; and
forming a phase change memory layer within the via.

9. The method of claim 8, wherein the liner material provides wetting properties for forming the phase change memory element.

10. The method of claim 8, wherein the liner is comprised of boron nitride (BN), aluminum nitride (AlN), silicon nitride (SiN), and/or aluminum oxide (AlO).

11. The method of claim 8, wherein the liner is formed by a conformal deposition process, such as Atomic Layer Deposition (ALD) or Plasma-Enhanced Atomic Layer Deposition (PALD).

12. The method of claim 8, further comprising:
forming a top electrode on top of the phase change memory element.

13. The method of claim 8, further comprising:
forming a second dielectric layer over the insulating dielectric layer;
etching the sidewall of the insulating dielectric layer.

14. The method of claim 13, wherein forming the via includes forming the via through the second dielectric layer.

15. The method of claim 14, wherein forming the liner includes depositing the liner, the liner forming a key-hole formation.

16. The method of claim 15, further comprising:
etching the second dielectric layer; and
forming a top electrode on top of the phase change memory element.

17. The method of claim 8, further comprising:
forming a spacer along the liner, the spacer being composed of a material having a higher thermal conductivity than the liner; and
etching a portion of the spacer, exposing the bottom electrode.

18. The method of claim 17, wherein the spacer material provides wetting properties for forming the phase change memory element.

19. The method of claim 17, wherein the spacer is formed by a conformal deposition process, such as Atomic Layer Deposition (ALD) or Plasma-Enhanced Atomic Layer Deposition (PALD).
